(19) United States
(12) Patent Application Publication
(10) Pub. No.: US 2017/0243832 A1
(43) Pub. Date: Aug. 24, 2017

(54) ELECTRONIC DEVICE MODULE AND METHOD OF MANUFACTURING THE SAME

(71) Applicant: SAMSUNG ELECTRO-MECHANICS CO., LTD., Suwon-si (KR)

(72) Inventors: Suk Youn HONG, Suwon-si (KR); Han Su PARK, Suwon-si (KR)

(73) Assignee: SAMSUNG ELECTRO-MECHANICS CO., LTD., Suwon-si (KR)

(21) Appl. No.: 15/263,445

(22) Filed: Sep. 13, 2016

(30) Foreign Application Priority Data
Feb. 18, 2016 (KR) 10-2016-0018976

(51) Int. Cl. H01L 23/552; H05K 1/02; H05K 3/32; H05K 3/00; H01L 21/56; H01L 21/3205; H01L 21/78; H05K 1/18; H01L 23/31

(52) U.S. Cl. CPC H01L 23/552; H05K 1/181; H05K 1/0215; H05K 1/0216; H05K 3/32; H01L 23/3121; H01L 23/3142; H01L 21/561; H01L 21/32051; H01L 21/78; H05K 3/0097; H05K 2203/1316

(57) ABSTRACT

An electronic device module, includes a substrate including a grounding electrode disposed on a surface of the substrate, an insulating portion encapsulating a portion of the surface of the substrate, an electronic component disposed on the surface of the substrate, wherein the electronic component is at least partially encapsulated by the insulating portion, and a sealing portion, having electrical conductivity, disposed on the substrate and the insulating portion. The sealing portion is electrically connected to the grounding electrode.

### CROSS-REFERENCE TO RELATED APPLICATION

This application claims the benefit under 35 USC 119(a) of Korean Patent Application No. 10-2016-0018976 filed on Feb. 18, 2016, with the Korean Intellectual Property Office, the entire disclosure of which is incorporated herein by reference for all purposes.

### BACKGROUND

1. Field

The following description relates to an electronic device module and a method of manufacturing the same.

2. Description of Related Art

Recently, demand for portable electronic products has increased in the market for electronics. To this end, the miniaturization and lightening of electronic components mounted on these systems is needed.

In order to achieve the miniaturization and lightening of such electronic components, there is demand for a technology to reduce the individual sizes of mounted components such as System On Chip (SOC) technology to make each of a plurality of devices a one-chip device, or System In Package (SIP) technology to integrate each of a plurality of devices into a single package.

In particular, high-frequency electronic device modules dealing with high-frequency signals, such as those used for receiving portable television (e.g., digital multimedia broadcasting (DMB) or digital video broadcasting (DVM)) signals, or network modules are desired to not only be miniaturized, but also to have various structures for shielding module components against electromagnetic waves so that the characteristics of shielding against electromagnetic interference (EMI) may be implemented effectively.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An aspect of the present disclosure may provide an electronic device module and a method of manufacturing the same, including a structure to block electromagnetic waves that protects an individual device in the interior thereof from external impacts, and has excellent resistance to electromagnetic interference (EMI) or electromagnetic waves.

In one general aspect, an electronic device module, includes a substrate including a grounding electrode disposed on a surface of the substrate, an insulating portion encapsulating a portion of the surface of the substrate, an electronic component disposed on the surface of the substrate, wherein the electronic component is at least partially encapsulated by the insulating portion, and a sealing portion, having electrical conductivity, disposed on the substrate and the insulating portion. The sealing portion is electrically connected to the grounding electrode.

The electronic device module may further include a shielding member disposed on a surface of the sealing portion.

The sealing portion may include a resin material having electrical conductivity.

The sealing portion may include an anisotropic conductive epoxy resin.

The insulating portion may include an underfill resin encapsulating the portion of the substrate connected to the electronic component. The grounding portion may be exposed on the surface of the substrate and is in direct contact with the sealing portion.

The insulating portion may include a cap-type structure with an inner cavity encapsulating the electronic component.

The shielding member may be formed only on a top surface of the sealing portion. The shielding member may be electrically connected to the grounding electrode through the sealing portion.

The insulating portion electrically may insulate contacts between the electronic component and the substrate, and fixes the electric component to the substrate.

In another general aspect, a method of manufacturing an electronic device module, includes mounting an electronic component on a surface of a substrate having a grounding electrode disposed on the surface of the substrate, forming an insulating portion sealing a portion of the substrate to which the electronic component is connected, and forming a sealing portion on the substrate by encapsulating the electronic component and insulating portion using a material having electrical conductivity.

The method may further include a forming of a conductive shielding member on a surface of the sealing portion.

The sealing portion may include a resin material having electrical conductivity.

The forming of the insulating portion may be performed by disposing the insulating portion on the substrate to allow the electronic component to be encapsulated by the insulating portion. The insulating portion may have a cap-type structure including an inner cavity and open bottom surface.

The substrate may be a strip-shaped substrate including a plurality of individual module mounting regions disposed on the substrate. The method may further include cutting of the strip-shaped substrate into the individual module mounting region after the forming of the shielding member.

The forming of the shielding member may include forming of a conductive film only on a top surface of the sealing portion.

The forming of the shielding member may be performed using a spray coating method.

Other features and aspects will be apparent from the following detailed description, the drawings, and the claims.

### BRIEF DESCRIPTION OF DRAWINGS

FIG. 1 is a cross-sectional view of an electronic device module, according to an embodiment;

FIG. 2 is a partially-cut perspective view of an interior of the electronic device module of FIG. 1;

FIGS. 3A to 3F are views illustrating different stages of a method of manufacturing an electronic device module, in order of processing, according to an embodiment;

FIG. 4 is a cross-sectional view of an electronic device module according to an embodiment; and

FIGS. 5A to 5C are views illustrating different stages of a method of manufacturing the electronic device module of FIG. 4.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The electronic device module and the method of manufacturing the same protects a passive device or a semiconductor chip included in the module from an external environment and blocks electromagnetic waves.

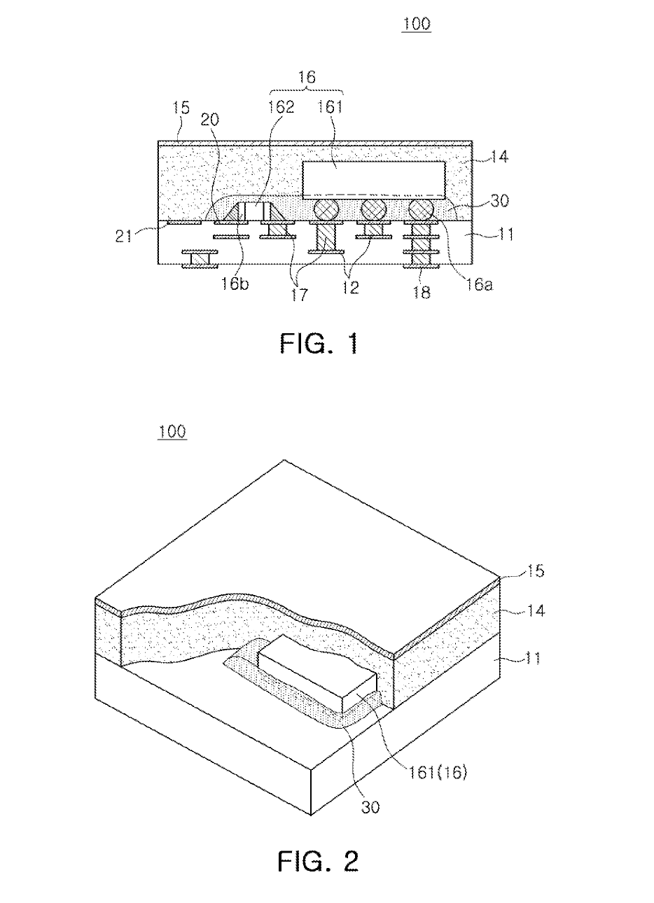

FIG. 1 is a cross-sectional view of an electronic device module according to an embodiment, and FIG. 2 is a partially-cut perspective view of an interior of the electronic device module of FIG. 1.

With reference to FIGS. 1 and 2, an electronic device module 100 includes a substrate 11, an electronic component 16, a sealing portion 14, and a shielding member 15.

A mounting electrode 20 for mounting the electronic component 16 and a grounding electrode 21 are disposed in a top surface of the substrate 11. In addition, a wiring pattern electrically connecting the mounting electrodes 20 to each other may also be disposed in the top surface of the substrate 11. At least one electronic component 16 is mounted on the mounting electrode 20.

The grounding electrode 21 is electrically connected to a ground terminal of the electronic components 16, through the wiring pattern, and the sealing portion 14 detailed below.

The substrate 11 may be provided using various types of circuit boards, such as a ceramic substrate, a printed circuit board, or a flexible substrate, for example only. However, embodiments are not limited thereto. The substrate 11 according to an embodiment may be a multilayer substrate formed to have a plurality of layers. In addition, a circuit pattern 12 may be formed between the layers.

In addition, the substrate 11 may include a plurality of external electrodes 18 disposed on a bottom surface of the substrate 11 for connection with one or more external components. Furthermore, a conductive via 17, connecting the mounting electrode 20, the circuit pattern 12, and the external electrodes 18 to each other, is formed within the substrate 11.

The electronic component 16 may include various electronic devices, such as a passive device and/or an active device. In other words, the electronic component 16 may be any electronic device that is capable of being mounted on or within the substrate 11.

The electronic component 16 includes a first external connection terminal 16a and a second external connection terminal 16b. In addition, the electronic component 16 may be electrically connected to the circuit pattern 12 in the substrate 11 and the external electrodes 18 through the first external connection terminal 16a and the second external connection terminal 16b. The first external connection terminal 16a and the second external connection terminal 16b may be encapsulated, enclosed, encased, covered, or enveloped by, or embedded in an insulating portion 30. Therefore, at least a portion of the electronic component 16 and substantially all of the first and second connection terminals 16a and 16b may be surrounded and encapsulated by the insulating portion 30.

The insulating portion 30 allows a conductive member, electrically connecting the electronic components 16 to the mounting electrodes 20, circuit pattern 12, conductive vias 17, or external electrodes 18, or any combination thereof, in the substrate 11, to be separated from the sealing portion 14 detailed below. Therefore, the insulating portion 30 keeps the first external connection terminal 16a and the second external connection terminal 16b of the electronic component 16 and the mounting electrodes 20 of the substrate 11, separate from the sealing portion 14. Thus, the insulating portion 30 is disposed to encapsulate an entirety of the first external connection terminal 16a and the second external connection terminal 16b, connecting the electronic component 16 to the electrical components of the substrate 11.

The electronic component 16 includes a flip-chip bonded electronic component 161 and chip-type electronic component 162. In the case of the flip-chip electronic component 161 is mounted using a flip-chip bonding method and the insulating portion 30 is filled between the flip-chip bonded electronic component 161 and the substrate 11, and encapsulates a portion of the flip-chip bonded electronic component 161 and the first external connection terminal 16a. In addition, in the case of the chip-type electronic component 162, the insulating portion 30 may be configured to encapsulate an entirety of the chip-type electronic component 162.

According to an embodiment, the insulating portion 30 may be formed of an underfill resin, for example, an epoxy resin, but embodiments are not limited thereto. In addition, the insulating portion 30 protects the first external connection terminal 16a and the second external connection terminal 16b of the electronic component 16, and improves adhesive strength between the electronic component 16 and the substrate 11, thus enhancing bonding reliability.

The grounding electrode 21 is external to the insulating portion 30. In addition, the insulating portion 30 may be formed to have various forms, depending on positions of the mounting electrodes 20 connected to the first external connection terminal 16a and the second external connection terminal 16b and the grounding electrode 21.

The sealing portion 14 is disposed between the substrate 11 and the shielding member 15 to seal the electronic component 16. The sealing portion 14 surrounds an exterior of the electronic component 16 securing it in place, thereby safely protecting the electronic component 16 from external impacts.

The sealing portion 14 according to an embodiment includes a material having electrical conductivity. For example, the sealing portion 14 may include a resin material having electrical conductivity, and may use a conductive epoxy resin or an anisotropic conductive epoxy resin. Since the sealing portion 14 has electrical conductivity, the sealing portion 14 electrically connects the grounding electrode 21 to the shielding member 15. Therefore, the electronic device module 100 according to an embodiment does not require a separate element to electrically connect the shielding member 15 to the grounding electrode 21 of the substrate 11.

The shielding member 15 prevents unnecessary electromagnetic waves from flowing therethrough. In addition, the shielding member 15 prevents electromagnetic waves generated by the electronic component 16 from being radiated outward or externally through the shielding member 15. The shielding member 15 is disposed in a form of a covering on a top surface of the sealing portion 14. In addition, the shielding member 15 according to an embodiment is formed on only a top surface of the sealing portion 14.

It may be desirable to ground the shielding member 15 to shield components against electromagnetic waves. To this end, the sealing portion 14 having electrical conductivity is used in the electronic device module 100 according to an embodiment.

The shielding member 15 may be formed of various materials having conductivity. The shielding member 15 according to an embodiment may be formed by a resin material having a conductive powder is coated on or a metal thin film is formed on an external surface of the sealing portion 14. In the case that the shielding member 15 is formed using a metal thin film, various techniques, such as sputtering, vapor deposition, electroplating, and electroless plating, may be used.

For example, the shielding member 15 according to an embodiment may be provided as the metal thin film formed on the external surface of the sealing portion 14 using a spray coating (conformal coating) method. The spray coating method has advantages of forming a uniform coating film and costing less in facility investment as compared with other processes. However, embodiments are not limited thereto, and the metal thin film may be formed using a screen printing method, for example, or any other method.

In addition, the shielding member 15 may include a conductive resin, such as a conductive epoxy resin. In this case, the shielding member 15 may include the conductive resin having higher electrical conductivity than that of the sealing portion 14.

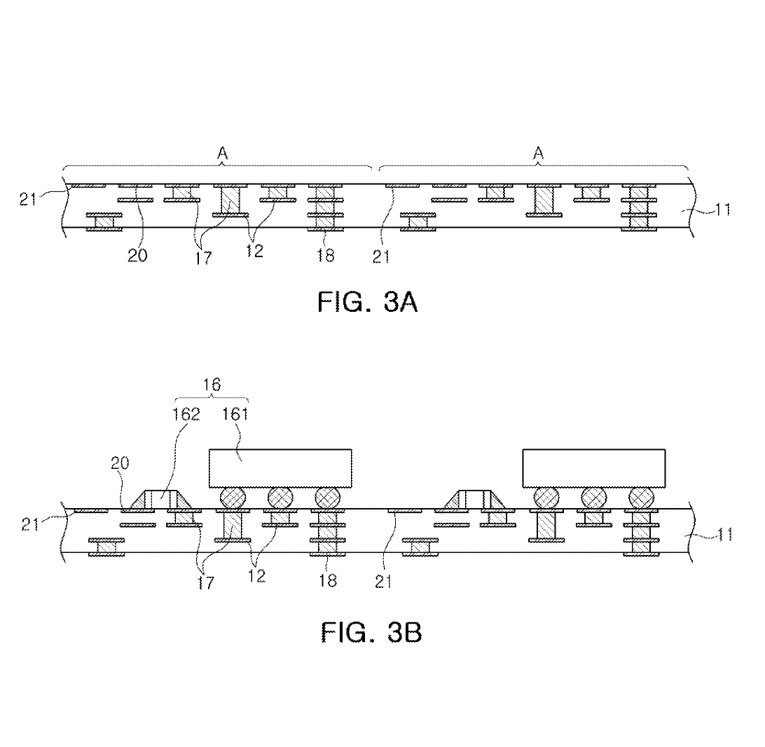

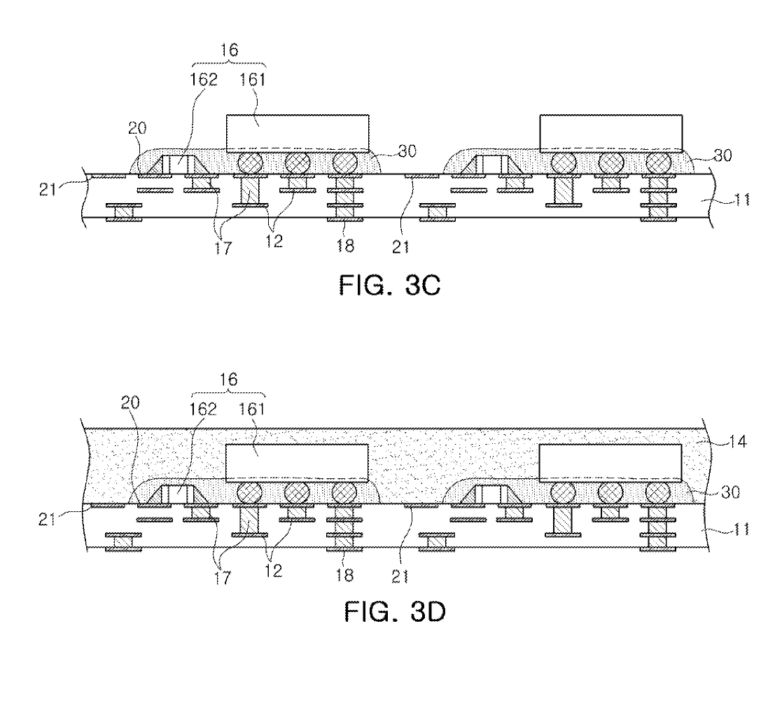

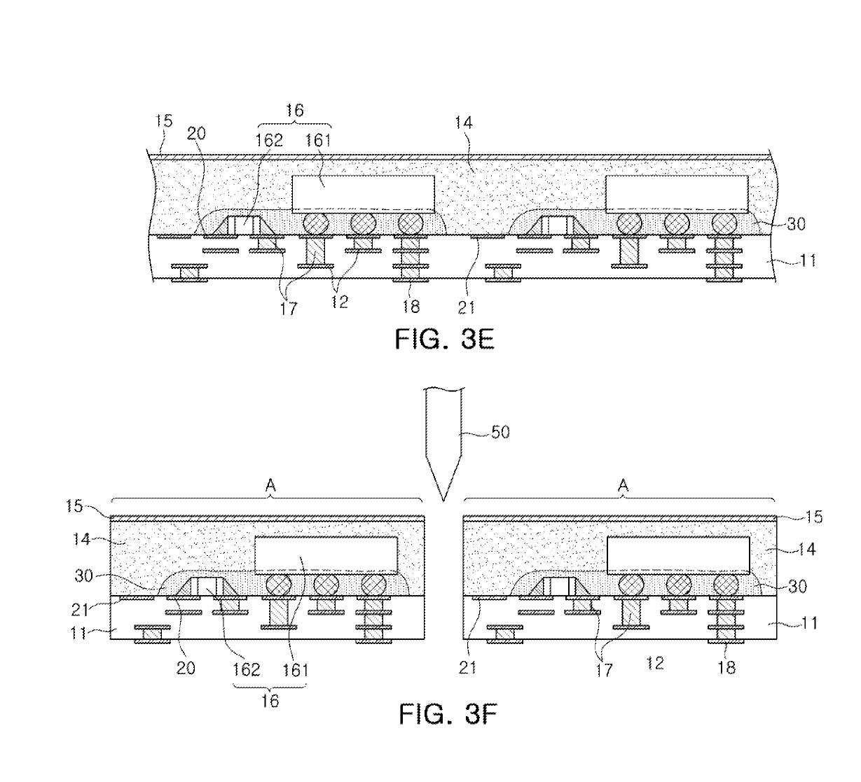

FIGS. 3A to 3F are views illustrating different stages of a method of manufacturing an electronic device module in order of processing according to an embodiment.

In reference to FIG. 3A, a substrate 11 is provided. The substrate 11 according to an embodiment may be a multilayer circuit board. In addition, electrically connected circuit patterns 12 may be formed between the layers of the substrate 11. A mounting electrode 20 and a grounding electrode 21, are formed in a top surface of a substrate.

The substrate 11 according to the embodiment may be provided as a strip-shaped substrate (hereinafter, a strip substrate). The strip substrate is formed to allow a plurality of individual electronic device modules 100 simultaneously manufactured. In addition, the strip substrate 11 is divided into a plurality of individual electronic device module regions A. In each of the plurality of individual electronic device module regions A, the plurality of electronic device modules 100 may be manufactured simultaneously.

Subsequently, as illustrated in FIG. 3B, an electronic component 16 is mounted on a surface of the substrate 11. As described above, in the case that the strip substrate is used, the electronic components 16 are each mounted entirely within individual electronic device module regions A of the strip substrate 11.

Subsequently, as illustrated in FIG. 3C, an insulating portion 30 is formed. A liquid underfill resin may be injected between the substrate 11 and the flip-chip bonded electronic component 161 and may go through a separate hardening process to be hardened to form the insulating portion 30.

In addition, a chip-type electronic component 162 is coated with the liquid underfill resin. Subsequently, the liquid underfill resin is hardened to form the insulating portion 30 with the chip-type electronic component embedded therein. In this case, viscosity of the underfill resin may be adjusted so that the underfill resin encapsulates the electronic component 16 without covering the grounding electrode 21. Therefore, an entirety of the mounting electrodes 20 of the substrate 11 are embedded by the insulating portion 30, while only the grounding electrode 21 is exposed outwardly of the insulating portion 30.

Subsequently, as illustrated in FIG. 3D, the electronic component 16 is sealed, and a sealing portion 14 is formed on the surface of the substrate 11.

In the case that the strip substrate 11 is used, the sealing portion 14 may be integrally formed over multiple electronic device module regions (regions A illustrated in FIG. 3A) of the strip substrate 11,and an entirety thereof are covered. However, the sealing portion 14 may be formed by dividing the individual electronic device module regions A as desired.

As described above, the sealing portion 14 may be formed of a material having electrical conductivity, such as a conductive epoxy resin, and is disposed on the substrate 11.

The method of manufacturing the electronic device module according to an embodiment may further include forming the sealing portion 14 and removing an upper portion thereof. The process may be performed by polishing an upper portion of the sealing portion 14 using a grinder, for example. Accordingly, a thickness of the sealing portion 14 may be significantly reduced. In addition, a thickening of an entirety of the electronic component module 100 due the sealing portion may be prevented.

Subsequently, as illustrated in FIG. 3E, a shielding member 15 is formed on the external surface of the sealing portion 14. The shielding member 15 is formed on only a top surface of the sealing portion 14. As described above, the shielding member 15 may be formed using a metal thin film. In addition, the metal thin film may be formed by applying a spray coating method. However, embodiments are not limited thereto, and the shielding member 15 may be formed in various methods, such as a screen printing method, a painting method, or a vapor deposition method, or any combination thereof.

Subsequently, as illustrated in FIG. 3F, the individual electronic device module 100 is formed by cutting the strip substrate 11 into individual electronic device module regions A. An entirety of the sealing portion 14 including the shielding member 15 formed thereon and the substrate 11 is cut using a blade 50. However, embodiments are not limited thereto and may be cut using various methods, such as laser or plasma cutting, In this case, the strip substrate 11 is cut based on a boundary of the individual electronic device module region A, using the blade 50. Thus, the electronic device module 100 illustrated in FIG. 1 is completed.

Since the shielding member 15 is formed on only an upper most surface, and the cutting of the strip substrate 11 is performed, the shielding member 15 is not formed on a side surface of the electronic device modules 100 according to the embodiment. However, since the sealing portion 14 has electrical conductivity, electromagnetic waves flowing in through the side surface may be blocked.

The cutting of the strip substrate 11 may also be performed before the shielding member 15 is formed. For example, before the shielding member 15 is formed, the strip substrate 11 is first cut to form the individual electronic device regions A as an unfinished product, so that the shielding member 15 may be formed on each of the individual electronic device modules 100.

In this case, although the shielding member 15 may also be formed on a side surface of the sealing portion 14, a process of forming the shielding member 15 may be relatively complex.

In the case of an electronic device module configured as above according to one or more embodiments, a sealing portion and/or a shielding member may protect an electronic component mounted on a substrate from external force, and may block electromagnetic waves. In addition, since the sealing portion is used without a separate component provided when the shielding member is grounded, the shielding member may be easily grounded. Thus, time spent in manufacturing the electronic device module 100 may be significantly reduced. In addition, since the sealing portion has electrical conductivity, electromagnetic waves may be blocked by only the sealing portion. Therefore, the electronic device module according to an embodiment may include a shielding member thicker than that of the prior art coating film, thus significantly increasing a shielding effect.

In addition, a grounding electrode is electrically connected to the shielding member through the sealing portion having electrical conductivity. The prior art generally uses a method in which an electrode is exposed on a side surface of the substrate, thereby electrically connecting the electrode to the shielding member. In the case of the prior art, the shielding member is also formed on the side surface of the substrate. Therefore, there was a problem in which the shielding member formed on the side surface of the substrate is electrically connected to other electrodes besides the grounding electrode, thus causing a current to flow. However, according to one or more embodiments, since the shielding member is not extended to the side surface of the substrate, greater reliability may be secured than in an electronic device module according to the prior art.

The electronic device module is not limited to an embodiment described above, and may be variously applied. The electronic device module according to an embodiment described below has a similar structure to that of the electronic device module (100 in FIG. 1) in an embodiment described above, but has a different form of insulating portion. Therefore, a detailed description of the same components will be not be repeated, and a further detailed description based on the insulating portion will be provided. In addition, the same components as those of an embodiment described above will be described using the same reference character.

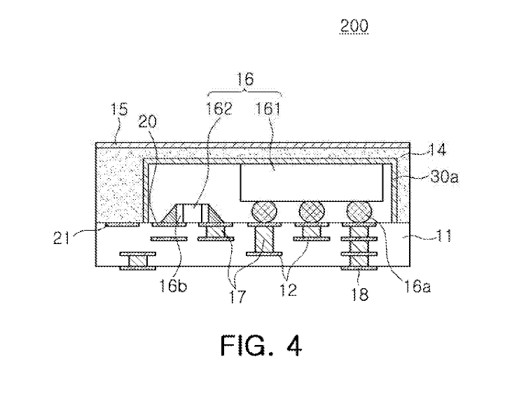

FIG. 4 is a cross-sectional view of an electronic device module according to an embodiment. In reference to FIG. 4, an electronic device module 200 is configured in a similar manner to the electronic device module (100 in FIG. 1) as described above, and has a difference in only terms of a structure of an insulating portion 30a.

In the case of the electronic device module 200 according to an embodiment, the insulating portion 30a is not formed of an underfill resin, but is formed to have a cap-type structure. The insulating portion 30a according to the embodiment includes an open bottom surface, and is formed to have a structure including internal space to be mounted on a substrate 11. The electronic components 16 and mounting electrodes 20 are mounted on the substrate 11 and disposed within the internal space of the insulating portion 30a. Therefore, a grounding electrode 21 is disposed externally of the insulating portion 30a.

The insulating portion 30a may be formed to have various forms, corresponding to positions of the electronic components 16. In addition, a cavity of the insulating portion 30a may further be filled with an insulating material, such as a resin.

A sealing portion 14 is disposed over the insulating portion 30a and a shielding member 15 is disposed on an upper surface of the sealing portion 14. Due to the insulating portion 30a, the sealing portion does not contact the electronic components 16.

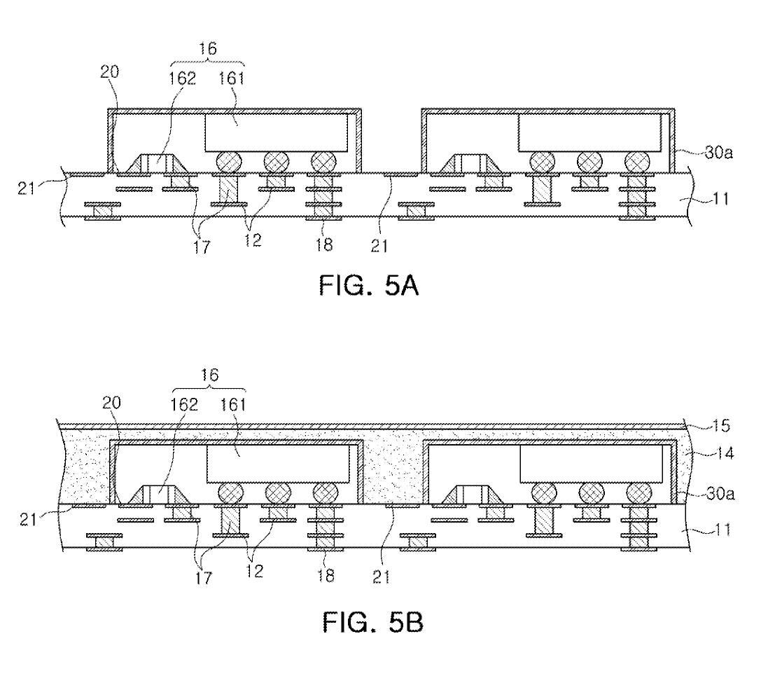

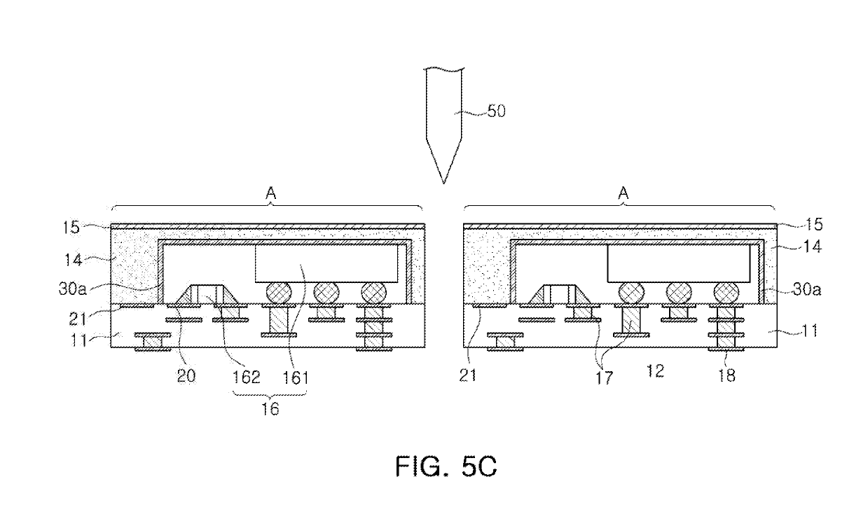

FIGS. 5A to 5C are views illustrating stages of a method of manufacturing an electronic device module 200.

According to an embodiment, an electronic device module 200 is manufactured in a similar manner to the method of manufacturing the electronic device module 100 as described above, but has a difference only in forming an insulating portion 30a. In more detail, the method of manufacturing the electronic device module 200 is implemented in the same manner as that of an embodiment described above, until the electronic component 16 is mounted (See FIG. 3B). Therefore, a description thereof will not be repeated.

Referring to FIG. 5A, after the electronic components 16 are mounted onto the substrate 11, a cap-type insulating portion 30a is disposed over the electronic components 16 and on the substrate 11. Thus, an entirety of the electronic components 16 and mounting electrodes 20 are disposed within the insulating portion 30a, while grounding electrodes 21 are disposed externally of the insulating portion 30a.

Subsequently, as illustrated in FIG. 5B, a sealing portion 14 and a shielding member 15 are formed in sequence covering the substrate 11 and insulating portion 30a. In the same manner as an embodiment described above, the sealing portion 14 includes a material having electrical conductivity, such as a conductive epoxy resin. In addition, the shielding member 15 includes a metal thin film or a conductive resin.

Subsequently, as illustrated in FIG. 5C, a strip substrate 11 including the sealing portion 14 and the shielding member 15 formed therein is cut into individual electronic device module regions A to complete the electronic device module 200.

An insulating portion 30a of an electronic device module 200 according to an embodiment, configured as described above, is separately manufactured. However, in the same manner as an embodiment described above, hardening the insulating portion 30 (see FIG. 3C) may be omitted.

In addition, in a case in which a plurality of insulating portions 30a are manufactured as a single connected structure to be disposed in a plurality of individual electronic device module regions, the insulating portions may be disposed in each of the individual electronic device module regions simultaneously, through a process in which the structure is disposed on a strip substrate 11. Thus, the manufacturing of the electronic device module may be facilitated.

As set forth above, according to an embodiment, an electronic device module 200 may include a grounding electrode 20 and a shielding member 15, electrically connected to each other through a sealing portion 14 having electrical conductivity. Therefore, manufacturing of the electronic device module may be facilitated.

As a non-exhaustive example only, an electronic product as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device configured to perform wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic device module, comprising:
a substrate including a grounding electrode disposed on a surface of the substrate;
an insulating portion encapsulating a portion of the surface of the substrate;
an electronic component disposed on the surface of the substrate, wherein the electronic component is at least partially encapsulated by the insulating portion; and
a sealing portion, having electrical conductivity, disposed on the substrate and the insulating portion;
wherein the sealing portion is electrically connected to the grounding electrode.

2. The electronic device module of claim 1, further comprising:
a shielding member disposed on a surface of the sealing portion.

3. The electronic device module of claim 1, wherein the sealing portion comprises:
a resin material having electrical conductivity.

4. The electronic device module of claim 1, wherein the sealing portion comprises:
an anisotropic conductive epoxy resin.

5. The electronic device module of claim 4, wherein the insulating portion comprises:
an underfill resin encapsulating the portion of the substrate connected to the electronic component.

6. The electronic device module of claim 1, wherein the insulating portion comprises a cap-type structure with an inner cavity encapsulating the electronic component.

7. The electronic device module of claim 2, wherein the shielding member is formed only on a top surface of the sealing portion.

8. The electronic device module of claim 7, wherein the shielding member is electrically connected to the grounding electrode through the sealing portion.

9. The electronic device module of claim 5, wherein the grounding portion is exposed on the surface of the substrate and is in direct contact with the sealing portion.

10. The electronic device module of claim 1, wherein the insulating portion electrically insulates contacts between the electronic component and the substrate, and fixes the electric component to the substrate.

11. A method of manufacturing an electronic device module, comprising:
mounting an electronic component on a surface of a substrate having a grounding electrode disposed on the surface of the substrate;
forming an insulating portion sealing a portion of the substrate to which the electronic component is connected; and
forming a sealing portion on the substrate by encapsulating the electronic component and insulating portion using a material having electrical conductivity.

12. The method of claim 11, further comprising:
a forming of a conductive shielding member on a surface of the sealing portion.

13. The method of manufacturing an electronic device module of claim 11, wherein the sealing portion comprises:
a resin material having electrical conductivity.

14. The method of claim 11, wherein the forming of the insulating portion is performed by disposing the insulating portion on the substrate to allow the electronic component to be encapsulated by the insulating portion,
wherein the insulating portion has a cap-type structure including an inner cavity and open bottom surface.

15. The method of claim 12, wherein the substrate is a strip-shaped substrate including a plurality of individual module mounting regions disposed on the substrate, the method further comprising:
cutting of the strip-shaped substrate into the individual module mounting region after the forming of the shielding member.

16. The method of claim 12, wherein the forming of the shielding member comprises forming of a conductive film only on a top surface of the sealing portion.

17. The method of claim 12, wherein the forming of the shielding member is performed using a spray coating method.
